(19) United States
(12) Patent Application Publication
(10) Pub. No.: US 2022/0076981 A1
(43) Pub. Date: Mar. 10, 2022

(54) SEALING DEVICE FOR A PEDESTAL ASSEMBLY

(71) Applicant: Applied Materials, Inc., Santa Clara, CA (US)

(72) Inventors: Lakshmikanth Krishnamurthy SHIRAHATTI, Bangalore (IN); Kirankumar Neelasandra SAVANDAIAH, Bangalore (IN); Thomas BREZOCZKY, Los Gatos, CA (US); Ganesh SUBBUSWAMY, Bangalore (IN)

(21) Appl. No.: 17/014,474

(22) Filed: Sep. 8, 2020

(51) Int. Cl. H01L 21/683; H01L 21/687; H01L 21/67

(52) U.S. Cl. CPC H01L 21/6833; H01L 21/67098; H01L 21/67126; H01L 21/68785

(57) ABSTRACT

A substrate support for a processing region comprises a compliant sealing device comprising. The compliant sealing device comprises a coupling mechanism, a sealing device body, and a bellows. The coupling mechanism comprises a mating surface configured to interface with an opposing surface of an electrostatic chuck. The mating surface is configured to form a separable seal when disposed against the opposing surface of the electrostatic chuck. The sealing device body is connected to the coupling mechanism and comprises a passageway. The bellows surrounds the sealing device body.

### BACKGROUND

### Field

Embodiments of the present disclosure generally relate to a methods and apparatus for processing substrates. More particularly, embodiments of the disclosure relate to substrate processing platforms, which use multiple processing regions for processing substrates.

### Description of the Related Art

Conventional semiconductor wafer processing equipment, typically referred to as cluster tools, are configured to perform one or more processes during substrate processing. For example, a cluster tool can include a physical vapor deposition (PVD) chamber to perform a PVD process on a substrate, an atomic layer deposition (ALD) chamber for performing an ALD process on a substrate, a chemical vapor deposition (CVD) chamber for performing CVD processes on a substrate, and/or one or more other processing regions.

In semiconductor wafer processing equipment, substrate supports are used for retaining substrates (or wafers) during processing. The substrate rests on a susceptor, for example an electrostatic chuck. Electrostatic chucks (or chuck) secure a substrate by creating an electrostatic attractive force between the substrate and the electrostatic chuck. A voltage applied to one or more insulated electrodes in the electrostatic chuck induces opposite polarity charges in the surface of the substrate and substrate supporting surface of the electrostatic chuck, respectively. The opposite charges generate a “chucking force” which causes the substrate to be pulled onto or attracted to the substrate supporting surface of the electrostatic chuck, thereby retaining the substrate. Conventional electrostatic chuck designs include assemblies that are inseparable due to the need to form good thermal and electrical coupling with various internal (e.g., cooling channels, electrical wires/leads connections) and external components (e.g., power supplies), and allow portions of the electrostatic chuck assembly to be disposed within a vacuum environment.

Many thin film deposition and etch processes performed in conventional semiconductor wafer processing equipment employ single substrate processing regions that are attached to a mainframe of the cluster tool, wherein a single substrate is loaded into a dedicated vacuum process chamber having dedicated hardware therein to support the substrate during a process performed thereon. The time required to load and unload the substrate from the dedicated chamber using a robot that is able to pick up and transfer one wafer at a time, which commonly includes the time needed to chuck and de-chuck the substrate from the substrate support in each process chamber, adds overhead time to the total time required to process a substrate in a cluster tool, decreases throughput and increases cost of ownership (CoO).

Thus, the aforementioned cluster tools and substrate supporting hardware have limitations, such as mechanical throughput, thermal stability during processing, and process flexibility. Therefore, what is needed in the art is a transfer apparatus for the cluster tool capable of improving the mechanical throughput, thermal stability, and increasing process flexibility. Thus, there is also a need for a substrate support assembly and substrate transfer mechanism, and method of using the same, that solves the problems described above.

### SUMMARY

In one example, a substrate support for a processing region comprises a compliant sealing device comprising. The compliant sealing device comprises a coupling mechanism, a sealing device body, and a bellows. The coupling mechanism comprises a mating surface configured to interface with an opposing surface of an electrostatic chuck. The mating surface is configured to form a separable seal when disposed against the opposing surface of the electrostatic chuck. The sealing device body is connected to the coupling mechanism and comprises a passageway. The bellows surrounds the sealing device body.

In one example, a compliant sealing device comprises a coupling mechanism, a sealing device, and a bellows. The coupling mechanism comprises a mating surface configured to interface with an opposing surface of an electrostatic chuck. The mating surface is configured to form a separable seal when disposed against the opposing surface of the electrostatic chuck. The sealing device body is connected to the coupling mechanism and comprises a passageway. The bellows surrounds the sealing device body.

In one example, a processing region for processing a substrate comprises a processing volume, a gas supply, and a pedestal assembly. The pedestal assembly is disposed in the processing volume, and comprises a compliant sealing device. The compliant sealing device comprises a coupling mechanism configured to interface with an electrostatic chuck, a sealing device body connected to the coupling mechanism and comprising a passageway coupled to the gas supply, and a bellows surrounding the sealing device body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a plan view of a cluster tool assembly according to one embodiments.

FIGS. 2A and 2B are cross-sectional views of a processing region, according to one or more embodiments.

FIGS. 3 and 4 are schematic illustrations of pedestal assembly, according to one or more embodiments.

FIG. 5 is a top view a compliant sealing device, according to one or more embodiments.

FIG. 6 is a side view a compliant sealing device, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the apparatus and methods, it is to be understood that the disclosure is not limited to the details of construction or process steps set forth in the following description. It is envisioned that some embodiments of the present disclosure may be combined with other embodiments. Aspects of the disclosure provided herein generally provide a substrate processing system that includes at least one processing module that includes a plurality of processing regions coupled thereto and a substrate transferring device disposed within a transfer region of the processing module for transferring a plurality of substrates to two or more of the plurality of processing regions. The methods and apparatuses disclosed herein are useful for performing vacuum processing on substrates wherein one or more substrates are transferred within the transfer region of processing module that is in direct communication with at least a portion of a processing region of a plurality of separately isolatable processing regions during the process of transferring the one or more substrates. In some embodiments, a substrate is positioned and maintained on the same substrate support member (hereafter electrostatic chuck) during the process of transferring the substrate within the processing module and while the substrate is being processed in each of the plurality of processing regions.

Aspects of the disclosure provided herein generally provide a substrate processing system, or cluster tool assembly 100, that includes at least one processing module that includes a plurality of processing stations coupled thereto and a substrate transferring device disposed within a transfer region of the processing module for transferring a plurality of substrates to two or more of the plurality of processing stations. The methods and apparatuses disclosed herein are useful for performing vacuum processing on substrates wherein one or more substrates are transferred within the transfer region of processing module that is in direct communication with at least a portion of a processing region of a plurality of separately isolatable processing stations during the process of transferring the one or more substrates. In some embodiments, a substrate is positioned and maintained on the same substrate support member (hereafter electrostatic chuck) during the process of transferring the substrate within the processing module and while the substrate is being processed in each of the plurality of processing stations.

In the substrate processing system, or cluster tool assembly 100, both an electrostatic chuck and a substrate are transferred between processing regions of the cluster tool assembly 100. During substrate processing, a backside gas is supplied to a passageway of an electrostatic chuck to control the temperature uniformity of a substrate. However, as the electrostatic chuck and substrate are transferred between processing regions, backside gas may escape before reaching the passageway of the electrostatic chuck. is discussed further below, when, an improved sealing mechanism is described that forms a seal with an electrostatic chuck to prevent a backside gas from leaking out into surrounding environment before it reaches the passageway of the electrostatic chuck.

One or more embodiments of the present disclosure are directed towards an apparatus for substrate processing and a cluster tool including a transfer apparatus and a plurality of processing regions. The transfer apparatus is configured as a carousel in some embodiments, and the processing regions may include facilities to enable atomic layer deposition (ALD), chemical vapor deposition (CVD), physical vapor deposition (PVD), etch, cleaning, heating, annealing, and/or polishing processes. Other processing platforms may also be used with the present disclosure at the discretion of a user. The present disclosure is generally meant to provide a substrate processing tool with high throughput, increased adaptability, and a smaller footprint.

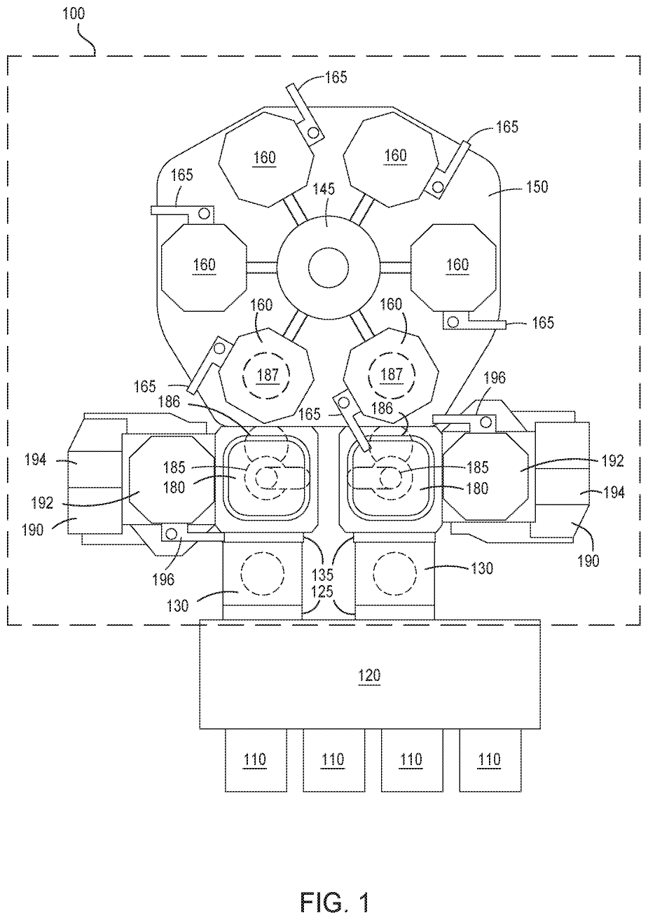

FIG. 1 is a plan view of a cluster tool assembly 100 with a single transfer chamber assembly 150. The cluster tool assembly 100 includes a plurality of load lock chambers 130, a plurality of robot chambers 180 adjacent to the plurality of load lock chambers 130, a plurality of prep chambers 190 adjacent to the plurality of robot chambers 180, and the transfer chamber assembly 150 adjacent to the plurality of robot chambers 180. The load lock chambers 130 of the cluster tool assembly 100 are typically coupled to a plurality of Front Opening Unified Pods (FOUPs) 110 by a Factory Interface (FI) 120 adjacent to the FOUPs 110.

The plurality of FOUPs 110 may be utilized to safely secure and store substrates as the substrates are moved between different machines. The plurality of FOUPs 110 may vary in quantity depending upon the process and throughput of the system. The FI 120 is disposed between the plurality of FOUPs 110 and the plurality of load lock chambers 130. The FI 120 creates an interface between the factory and the cluster tool assembly 100. The plurality of load lock chambers 130 are connected to the FI 120 by first valves 125, such that a substrate may be transferred from the FI 120 to the plurality of load lock chambers 130 through the first valves 125 and from the plurality of load lock chambers 130 to the FI 120. As shown, the first valves 125 are on one wall of the load lock chambers 130. In some embodiments, the first valves 125 are fluid isolation valves and form a seal between the FI 120 and the load lock chambers 130. This seal may keep outside contaminants from entering the cluster tool assembly 100. The load lock chambers 130 also comprise a second valve 135 on an opposite wall from the first valve 125. The second valve 135 interfaces the load lock chambers 130 with the robot chambers 180.

The transfer chamber assembly 150 includes a central transfer apparatus 145 and a plurality of processing stations 160. The plurality of processing stations 160 are disposed around the central transfer apparatus 145, such that the plurality of processing stations 160 are disposed radially outward of the central transfer apparatus 145 in the transfer chamber assembly 150.

As shown, the robot chambers 180 are on one side of the load lock chambers 130, such that the load lock chambers 130 are between the FI 120 and the robot chambers 180. The robot chambers 180 include a transfer robot 185. The transfer robot 185 may be any robot suitable to transfer one or more substrates from one chamber to another. The transfer robot 185 is utilized to transfer substrates 186 to a substrate support, which is also referred to herein as an electrostatic chuck (e.g., electrostatic chuck 187) that is temporarily connected to the central transfer apparatus 145. The connection between the electrostatic chuck 187 and the central transfer apparatus 145 is described below in more detail. The electrostatic chuck 187 holds a single substrate 186 and travels with the substrate 186 into each of the processing stations 160. The electrostatic chuck 187, when in one of the processing stations 160 (with a substrate thereon), forms a boundary of the processing station 160. The substrates 186 are mated with one electrostatic chuck 187, and the substrate 186 moves in and between the processing stations 160 on that electrostatic chuck 187.

In some embodiments, the transfer robot 185 is configured to transport substrates 186 from the load lock chambers 130 and into the plurality of prep chambers 190. The transfer robot 185 removes the substrate 186 from the load lock chambers 130, moves the substrate 186 into the robot chamber 180, and then moves the substrate 186 into the prep chamber 190. The transfer robot 185 is also be configured to move substrates 186 to the transfer chamber assembly 150. Similarly to how the substrate 186 may be moved to the prep chambers 190 from the load lock chambers 130 by the transfer robot 185, the substrate 186 may also be moved from the prep chamber 190 to the load lock chambers 130 by the transfer robot 185. The transfer robot 185 may also move substrates 186 from the transfer chamber assembly 150 to the prep chambers 190 or the load lock chambers 130. In some alternative embodiments, the transfer robot 185 may move a substrate 186 from the load lock chambers 130, move the substrate 186 into the robot chamber 180, and then move the substrate 186 into the transfer chamber assembly 150. In this alternative embodiment, the substrate 186 may not enter the prep chamber 190 either before processing in the transfer chamber assembly 150 or after processing in the transfer chamber assembly 150.

The prep chambers 190 include a cleaning chamber 192, a packaging structure 194, and a cleaning chamber vacuum pump 196. The cleaning chamber 192 may be any one of a pre-clean chamber, an anneal chamber, or a cool down chamber, depending upon the desired process within the cluster tool assembly 100. In some embodiments, the cleaning chamber 192 is a wet clean chamber. In other embodiments, the cleaning chamber 192 is a plasma clean chamber. In yet other exemplary embodiments, the cleaning chamber 192 is a Preclean II chamber available from Applied Materials, Inc., of Santa Clara, Calif.

The packaging structure 194 may be a structural support for the cleaning chamber 192. The packaging structure 194 may include a sub-transfer chamber (not shown), a gas supply (not shown), and an exhaust port (not shown). The packaging structure 194 may provide the structure around the cleaning chamber 192 and interface the cleaning chamber 192 to the robot chamber 180. The cleaning chamber vacuum pump 196 is disposed adjacent to a wall of the cleaning chamber 192 and provides control of the pressure within the cleaning chamber 192. One cleaning chamber vacuum pump 196 may be adjacent to each of the cleaning chambers 192. The cleaning chamber vacuum pump 196 may be configured to provide a pressure change to the cleaning chamber 192. In some embodiments, the cleaning chamber vacuum pump 196 is configured to increase the pressure of the cleaning chamber 192. In other embodiments, the cleaning chamber vacuum pump 196 is configured to decrease the pressure of the cleaning chamber 192, such as to create a vacuum within the cleaning chamber 192. In yet other embodiments, the cleaning chamber vacuum pump 196 is configured to both increase and decrease the pressure of the cleaning chamber 192 depending on the process being utilized within the cluster tool assembly 100. The cleaning chamber vacuum pump 196 may be held in place by the packaging structure 194, such that the packaging structure 194 at least partially surrounds the cleaning chamber vacuum pump 196.

The load lock chambers 130, robot chambers 180, and prep chambers 190 may be arranged to reduce the footprint required for the cluster tool assembly 100. In one embodiment, one load lock chamber 130 is attached to a first wall of the robot chamber 180. One prep chamber 190 is attached to a second wall of the robot chamber 180. The first and second walls may be adjacent walls on the robot chamber 180. In some embodiments, the robot chamber 180 is roughly square shaped. In other embodiments, the robot chamber 180 is a quadrilateral. In yet other embodiments, the robot chambers 180 may be any desired shape, such as a polygon or a round shape, such as a circle. In an embodiment where the robot chambers 180 are a square or quadrilateral shape, the first wall and the second wall may be adjacent walls, such that the two walls intersect each other. As shown in FIG. 1, the cluster tool assembly 100 includes two load lock chambers 130, two robot chambers 180, and two cleaning chambers 190. The two load lock chambers 130, two robot chambers 180, and two cleaning chambers 190, when arranged as described above, form two transport assemblies. The two transport assemblies are spaced apart from each other and form mirror images of one another, such that the prep chambers 190 are on opposite walls of their respective robot chambers 180.

As shown, the transfer chamber assembly 150 is adjacent to the robot chambers 180, such that the transfer chamber assembly 150 is connected to the robot chambers 180 by a valve (not shown). The transfer chamber assembly 150 may be attached to a third wall of the robot chambers 180. The third wall of the robot chambers 180 may be opposite the first wall of the robot chambers 180.

A chamber pump 165 is disposed adjacent to each of the processing stations 160, such that a plurality of chamber pumps 165 are disposed around the central transfer apparatus 145. The plurality of chamber pumps 165 may also be disposed radially outward of the central transfer apparatus 145 in the transfer chamber assembly 150. One chamber pump 165 for each of the processing stations 160 is provided, such that one chamber pump 165 is connected to each of the processing stations 160. In some embodiments, multiple chamber pumps 165 per processing station 160 are provided. In yet other embodiments, a processing station 160 may not have a chamber pump 165. A varying number of chamber pumps 165 per processing station 160 may be provided, such that one or more processing stations 160 may have a different number of chamber pumps 165 than a separate set of processing stations 160. In some embodiments, the chamber pumps 165 are configured to increase the pressure of the processing station 160. In other embodiments, the chamber pumps 196 are configured to decrease the pressure of the processing station 160, such as to create a vacuum within the processing station 160. In yet other embodiments, the chamber pumps 165 are configured to both increase and decrease the pressure of the processing stations 160 depending on the process being utilized within the cluster tool assembly 100.

In the embodiment shown in FIG. 1, the transfer chamber assembly 150 includes six processing stations 160. In one embodiment, the transfer chamber assembly 150 includes a single processing station 160. In another embodiment, two or more processing stations 160 are provided. In some embodiments two to twelve processing stations 160 are within the transfer chamber assembly 150. In other embodiments, four to eight processing stations 160 are within the transfer chamber assembly 150. The number of processing stations 160 impacts the total footprint of the cluster tool assembly 100, the number of possible process steps capable of being performed by the cluster tool assembly 100, the total fabrication cost of the cluster tool assembly 100, and the throughput of the cluster tool assembly 100.

The plurality of processing stations 160 can be any one of PVD, CVD, ALD, etch, cleaning, heating, annealing, and/or polishing platforms. In some embodiments, the plurality of processing stations 160 can all be similar platforms. In other embodiments, the plurality of processing stations 160 can include two or more types of processing platforms. In one exemplary embodiment, all of the plurality of processing stations 160 are PVD process chambers. In another exemplary embodiment, the plurality of processing stations 160 includes both PVD and CVD process chambers. Other embodiments of the makeup of the plurality of processing stations 160 are envisioned. The plurality of processing stations 160 can be altered to match the types of process chambers needed to complete a process.

The central transfer apparatus 145 is disposed in the center of the transfer chamber assembly 150, such that the central transfer apparatus 145 is disposed around a central axis of the transfer chamber assembly 150. The central transfer apparatus 145, may be any suitable transfer device. The central transfer apparatus 145 is configured to transport a substrate 186 on an electrostatic chuck 187 to and from each of the processing stations 160. In one embodiment, the central transfer apparatus 145 is configured as a carousel system.

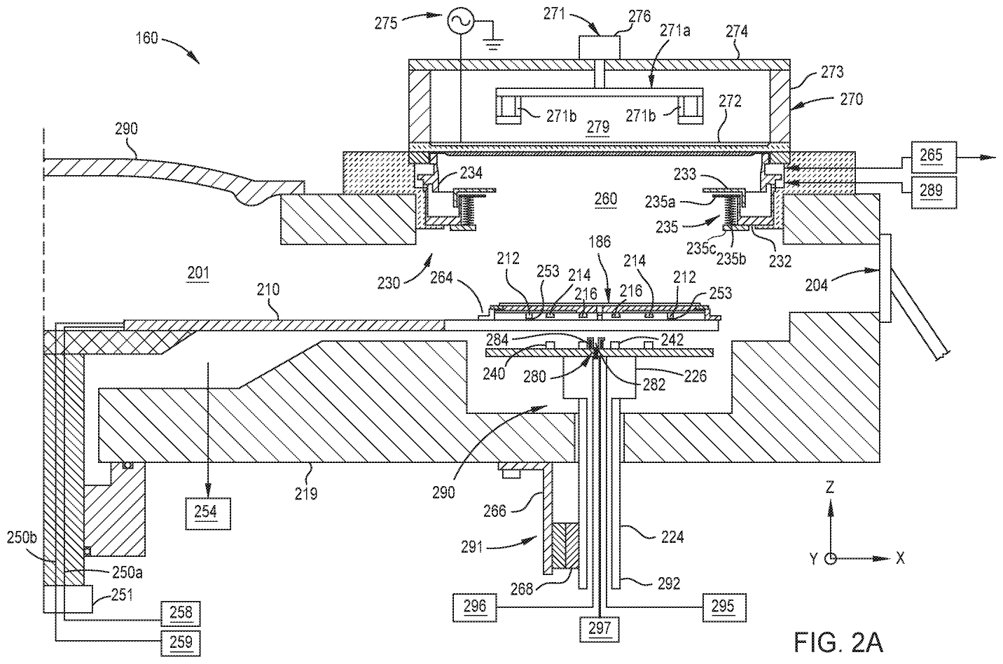

As shown in FIGS. 2A and 2B, a processing station 160 is serviced via a central transfer apparatus (e.g., the central transfer apparatus 145 of FIG. 1) to transfer electrostatic chucks (e.g., the electrostatic chuck 187) and substrates (e.g., the substrate 186) into and out of the processing station 160. A substrate transfer opening 204 extends inwardly of the outer surface of a circumferential wall of the processing station 160 and into a transfer region 201 of the processing station 160. The transfer opening 204 allows the transfer robot 185, to transfer the substrate 186 into and out of the transfer region 201. In various embodiments, the transfer opening 204 may be omitted. For example, in embodiments where the processing station 160 does not interface with the transfer robot 185, the transfer opening 204 may be omitted.

As illustrated in FIG. 2A, the electrostatic chuck 187 and the substrate 186 is supported by the transfer arm 210. For example, the terminals 212 of the electrostatic chuck 187 are mated with the electrical contacts (pins) 253 of the transfer arm 210. The transfer arm 210 is one of one or more transfer arms 210 of the central transfer apparatus 145. The electrostatic chuck 187 and the substrate 186 are transferred between processing stations 160 by the transfer arms 210 of the central transfer apparatus 145. Power sources 258 and 259 provide power supply signals to the electrical contacts 253 to power an electrical component or electrical components (e.g., heating elements and/or chucking electrodes, among others) within the electrostatic chuck 187 while the electrostatic chuck 187 and the substrate 186 are supported by the transfer arm 210 and moved between processing stations 160.

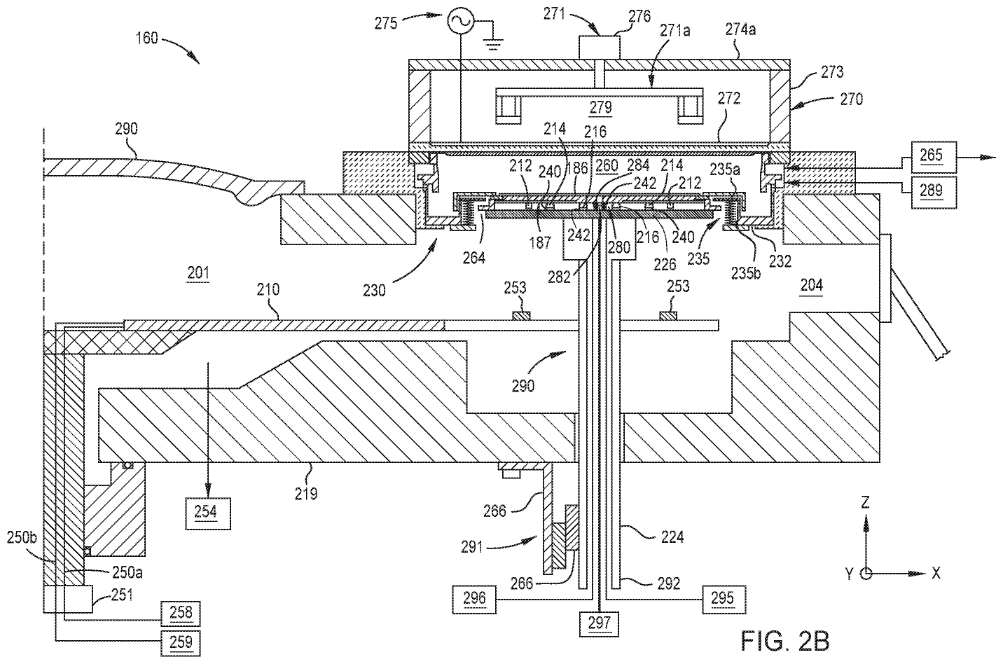

The electrical contacts 253 provide electrical power to an electrical component or components within the electrostatic chuck 187 while the electrostatic chuck 187 and substrate 186 are supported on the transfer arm 210. For example, one or more of the electrical contacts 253 are coupled to a power source 258 that provides direct current (DC) signals, e.g., a DC power source, via one or more connections 250a. The DC signals are coupled the chucking electrodes of the electrostatic chuck 187 (e.g., chucking electrodes 370 of FIG. 3) via the one or more electrical connections 250a. A first one of the DC signals has a positive polarity and a second one of the DC signals has a negative polarity. Further, the magnitude of the DC signals are substantially similar (e.g., within five percent of each other). For example, the magnitude of the DC signals is about 1000 V. Alternatively, the magnitude of the DC signals is less than or greater than about 1000 V. Driving the chucking electrodes 370 with the DC signals generates an electrical chucking force that holds the substrates 186 to the surface of the electrostatic chuck 187.

The power source 259 provides an alternating current (AC) signal or signals that is provided to the heating elements of an electrostatic chuck 187 (e.g., the heating elements 372) via one or more electrical connections 250b between one or more electrical contacts 253 and one or more terminals 214. The power source 259 may be referred to as an AC power source. The AC signal provide a current of about 30 A. Alternatively, the AC signal provides a current of less than or greater than 30 A. The AC signal or signals are converted by the heating elements 372 into heat that thermally couples with the substrate 186.

The conductors 250a, 250b are routed through an internal region of the transfer arm 210 to connect with the respective ones of the electrical contacts 253. The electrical contacts 253 are electrically coupled to the power sources 258 and 259 by use of a slip ring 251 that is adapted to allow electrical connections to be made to the electrical contacts 253 while the transfer arms 210 are rotated by a motor of the central transfer apparatus 145.

A source assembly 270 of the processing station 160 is configured to perform a deposition process (e.g., a PVD deposition process or the like). In this configuration, the source assembly 270 includes a target 272, a magnetron assembly 271, a source assembly wall 273, a lid 274, and a sputtering power supply 275. The magnetron assembly 271 includes a magnetron region 279 in which the magnetron 271a is rotated by use of a magnetron rotation motor 276 during processing. The target 272 and magnetron assembly 271 are typically cooled by the delivery of a cooling fluid (e.g., DI water) to the magnetron region 279 from a fluid recirculation device (not shown). The magnetron 271a includes a plurality of magnets 271b that are configured to generate magnetic fields that extend below the lower surface of the target 272 to promote a sputtering process in the processing volume 260 during a PVD deposition process.

Alternate configurations of the processing station 160, which are adapted to perform CVD, PECVD, ALD, PEALD, etch, or thermal processes, the source assembly 270 generally include different hardware components. In one example, the source assembly 270 of a processing station that is adapted to perform a PECVD deposition process or etch process includes a gas distribution plate, or showerhead, that is configured to deliver a precursor gas or etching gas into the processing volume 260 and across a surface of a substrate disposed within the processing station 160 during processing. In this case, the magnetron assembly 271 and target are not used, and the sputtering power supply 275 is replaced with an RF power supply that is configured to bias the gas distribution plate.

A substrate support actuation assembly 290 includes a pedestal lift assembly 291 and a pedestal assembly 224. The pedestal lift assembly 291 includes a lift actuator assembly 268 and a lift mounting assembly 266, which is coupled to the base 219 of the processing station 160. During operation the lift actuator assembly 268 and lift mounting assembly 266 are configured to position the pedestal assembly 224 in at least a transfer position (FIG. 2A), which is positioned vertically (Z-direction) below a transfer arm 210 (i.e., transfer plane), and a processing position (FIG. 2B), which is vertically above the transfer arm 210. Further, the lift actuator assembly 268 and the lift mounting assembly 266 apply vertical motion, in the +Z direction, to the pedestal assembly 224 to pick the electrostatic chuck 187 off of the transfer arm 210. Additionally, the lift actuator assembly 268 and the lift mounting assembly 266 apply vertical motion, in the −Z direction, to the pedestal assembly 224 to position the electrostatic chuck 187 on the transfer arm 210.

The lift actuator assembly 268 is coupled to a pedestal shaft 292, which is supported by bearings (not shown) that are coupled to a base 219 to guide the pedestal shaft 292 as it is translated by the lift actuator assembly 268. A bellows assembly (not shown) is used to form a seal between the outer diameter of the pedestal shaft 292 and a portion of the base 219, such that a vacuum environment created within the transfer region 201 by use of a pump 254 is maintained during normal operation.

The pedestal assembly 224 includes a substrate lift support 226 that is coupled to the pedestal shaft 292. The pedestal assembly 224 includes a heater power source 295, an electrostatic chuck power source 296 and a backside gas source 297. The substrate lift support 226 supports the electrostatic chuck 187 and the substrate 186 within the processing station 160.

The substrate lift support 226 comprises pins 240 and 242. The pins 240 are coupled to the heater power source 295. The pedestal assembly 224 includes two or more pins 240. Further, the pins 240 are configured to mate (e.g., physically and electrically couple) with terminals 214 of the electrostatic chuck 187. The heater power source 295 provides an AC power signal or signals. The heater power source 295 provides an AC power signal having a current in a range of about 20 A to about 30 A to the pins 240 which is provided to the heating elements (e.g., heating elements 372 of FIG. 3) via the terminals 214 when the pins 240 are mated with the terminals 214. In other embodiments, the heater power source 295 provides an AC power signal having a current of less than 20 A or greater than 30 A.

The pins 242 of the substrate lift support 226 mate with terminals 216 of the electrostatic chuck 187. The substrate lift support 226 includes two or more pins 242. In such embodiments, each of the pins 242 is configured to couple to a different one of the terminals 216. For example, a first one of the pins 242 is configured to couple to a first one of the terminals 216 and a second of the pins 242 is configured to couple to a second one of the terminals 216. The pins 242 are coupled to the electrostatic chuck power source 296.

The electrostatic chuck power source 296 provides DC power signals to the pins 242. The pins 242 couple the DC power signals to the terminals 216 and to chucking electrodes (e.g., the chucking electrodes 370 of FIG. 3) when the pins 242 are mated with the terminals 216 to electrically chuck the substrate 186 to the electrostatic chuck 187. In one embodiment, the electrostatic chuck power source 296 provides a positive DC power signal to a first one of the pins 242 and a negative DC power signal to a second one of the pins 242 to electrically chuck the substrate 186 to the electrostatic chuck 187. The DC power signals drive the pins 242, the terminals 212, and the chucking electrodes 370 in a bi-polar configuration such that a first DC power signal is positive and a second DC power signal is negative. The magnitudes of the DC power signals may be the same. For example, the first DC power signal is about 1500 V and the second DC power signal is about −1500 V. Alternatively, the DC power signals have a magnitude greater than or less than about 1500 V. In other embodiments, the magnitude of a first one of the DC power signals differs from the magnitude of a second one of the DC power signals.

The pins 240 and 242 are removably coupled or non-removably (or permanently) coupled to the pedestal assembly 224. For example, in one embodiment, the pins 240 and/or 242 are removably coupled and may be attached and removed from the pedestal assembly 224 such that the pins 240 and/or 242 may be replaced without damaging the pedestal assembly 224. The contact between the pins 240 and 242 and the terminals 214 and 216 causes wear to the pins 240 and 242. Over time, the pins 240 and 242 may need to be replaced. Removably coupling the pins 240 and 242 to the pedestal assembly 224 allows the pins 240 and 242 to be removed and replaced when wear affects the operation of the pins 240 and/or 242 and degrades the coupling between the pins 240, 242 and the terminals 214, 216.

The pedestal assembly 224 includes a compliant sealing device (e.g., flexible member) 280. The compliant sealing device 280 includes a passageway 282 and bellows 284. The compliant sealing device 280 is configured to generate a separable seal between a portion of a bottom surface 311 (FIG. 3), or also referred to herein as an opposing surface, of the electrostatic chuck 187. For example, a separable seal is formed between the compliant sealing device 280 and a first electrostatic chuck 187, the separable seal is broken and the first electrostatic chuck 187 is transferred from the pedestal assembly. A second electrostatic chuck 187 is transferred onto the pedestal assembly, and a separable seal is formed between the compliant sealing device 280 and the second electrostatic chuck 187. Therefore, during processing of a substrate in the various processing stations 160 within the system 100 an electrostatic chuck 187 can be connected and disconnected from a compliant sealing device 280 in each processing station 160 by positioning a mating surface 285A (FIGS. 3, 5 and 6) of the compliant sealing device 280 against the opposing surface of the electrostatic chuck 187 on a substrate lift support 226. The diameter of the opening in the compliant sealing device 280 is less than about five percent of the size of the electrostatic chuck 187 body. In other embodiments, the size of the opening of the compliant sealing device 280 is greater than about five percent of the size of the electrostatic chuck 187 body. A backside gas is provided via the backside gas source 297 to the passageway 282 of the compliant sealing device 280. The backside gas flows through the passageway 282 into the space between the substrate 186 and the electrostatic chuck 187 to improve the uniformity of the thermal conductivity between the substrate 186 and the electrostatic chuck 187, improving the uniformity of the deposition of materials onto the substrate 186. The backside gas may be nitrogen, helium, or argon, among others.

The electrostatic chuck 187 contacts a portion of the process kit assembly 230 for form the processing volume 260. The process kit assembly 230 includes a process region shield 232 and a sealing assembly 235. The processing volume 260A is evacuated via a vacuum pump 265 coupled a station wall 234 via a first port within the station wall 234. The station wall 234 is coupled to a gas source assembly 289, and is configured to deliver one or more process gases (e.g., Ar, N₂) to the processing volume 260 through a plenum during processing.

During processing of a substrate, e.g., FIG. 2B, the substrate 186 and the electrostatic chuck 187 are positioned in a processing position below the source assembly 270. When in the processing position, a region 264 of the electrostatic chuck 187 forms a separable seal with a portion of the sealing assembly 235 so as to substantially fluidly isolate the processing volume 260 from the transfer region 201. Thus, when in the processing position, the electrostatic chuck 187, the sealing assembly 235, the process region shield 232, the station wall 234, the isolation ring 233 and target 272 substantially enclose and define the processing volume 260. The sealing assembly 235 includes an upper plate 235a, bellows 235b, and a lower plate 235c. The bellows 235b is positioned between the upper plate 235a and the lower plate 235c. In some embodiments, the seal formed between the portion of the electrostatic chuck 187 and an upper plate 235a of the sealing assembly 235 is created at a sealing region that is formed by physical contact between a surface of the region 264 of the electrostatic chuck 187 and a surface of the upper plate 235a. In some embodiments, a flexible bellows assembly 235b of the sealing assembly 235 is configured to be extended in the vertical direction as the portion of the electrostatic chuck 187 is placed in contact with the surface of the portion of the sealing assembly 235 by use of the lift actuator assembly 268 in the substrate support actuation assembly 290. The compliant nature of the flexible bellows assembly allows any misalignment or planarity differences between the surface of the portion of the electrostatic chuck 187 and the surface of the portion of the sealing assembly 235 to be taken up so that a reliable, repeatable and separable seal can be formed at the region 264. The flexible bellows assembly 235b may be a stainless steel bellows assembly or Inconel bellows assembly, among others.

FIG. 3 illustrates a portion of the pedestal assembly 224, the electrostatic chuck 187, and the substrate 186, according to one or more embodiments. As is described above, the pedestal assembly 224 includes the compliant sealing device 280. The compliant sealing device 280 includes the passageway 282, the bellows 284, and a coupling mechanism 283.

The bellows 284 is configured to compress as electrostatic chuck 187 and a substrate 186 in response to the pedestal assembly 224 being loaded onto the pedestal assembly 224 to prevent an external gas from entering the passageway 282 and a gas flowing through the passageway 282 leaking out of the passageway 282.

The coupling mechanism 283 is configured to interface (e.g., contact) the bottom of the electrostatic chuck 187. The coupling mechanism 283 is part of the sealing device body 281. The coupling mechanism 283 forms a separable seal with the bottom of the electrostatic chuck 187 to prevent a backside gas flowing through the passageway 282 from leaking out of the passageway 282. Further, the passageway 282 is fluidly coupled with the passageway 317 of the electrostatic chuck 187 such that a backside gas flowing through the passageway 282 flows through the passageway 317 and into any space between the electrostatic chuck 187 and the substrate 186. The coupling mechanism 283 includes a raised element 285 that contacts the bottom of the electrostatic chuck 187. In some embodiments, the separable seal is unable to form a leak free seal, and is configured to form a seal that has a leak rate less than about 6e⁻¹¹ Kg/S of Argon, Nitrogen, and other gases. The passageway 282 is fluidly coupled to the passageway 317 via the compliant coupling device 280.

The coupling mechanism 283 may be formed from a single inseparable component that is formed from one or more compatible materials. For example, the coupling mechanism 283 and the raised element 285 may be formed from a single piece of material. In one embodiment, the coupling mechanism 283 is comprised of stainless steel. In other embodiments, the coupling mechanism 283 is comprised of aluminum oxide alloys, aluminum nitride alloys, and nickel-chromium alloys, among others.

The raised element 285 of the coupling mechanism 283 may have a flat surface, convex surface or a concave surface (e.g., mating surface 285A) that is configured to mate with an opposing surface of the electrostatic chuck 187. In some embodiments, the coupling mechanism 283 includes a mating surface 285A that is flat and has a low surface roughness (e.g., Ra<8 μin, or <4 μin) so that the mating surface 285A can mate with a portion of an opposing surface (i.e., bottom surface 311) of the electrostatic chuck 187, which is equally as flat and has a similar low surface roughness.

The force 310 couples the electrostatic chuck 187 with the coupling mechanism 283 of the compliant sealing device 280. The force 310 is the weight of the electrostatic chuck 187 and the substrate 186. For example, the weight of the electrostatic chuck 187 may be in a range of about 4 lbs. to about 10 lbs. In various embodiments, the weight of the electrostatic chuck 187 and the 186 may be less than about 4 lbs. or greater than about 10 lbs.

The compliant sealing device 280 supports a portion of the force applied of the electrostatic chuck 187 and the substrate 186. For example, the compliant sealing device 280 supports less than 35 percent (%) of the weight, such as between about 10 percent to about 25% of the weight, applied by the electrostatic chuck 187 and the substrate 186. Alternatively, the compliant sealing device 280 supports less than about 10 percent or more than about 25 percent of the force by the electrostatic chuck 187 and the substrate 186.

With further reference to FIG. 2A, the pedestal assembly 224 is positioned in a loading position to receive the electrostatic chuck 187 and the substrate 186. When the electrostatic chuck 187 and the substrate 186 electrostatic chuck 187 contacts the raised element 285, the weight of the electrostatic chuck 187 and the substrate 186 compresses the bellows 284 so that the generated spring force, created by the compression of the bellow 284 (e.g., Hooke's law), and the mating surface of the raised element 285 causes a separable seal to form between the bottom surface 311 of the electrostatic chuck 187 and the mating surface. The pedestal assembly 224 then raises the electrostatic chuck 187 and the substrate 186 into a processing position (FIG. 2B) and a backside gas passes through the passageway 282. By configuring the compliant sealing device 280 such that it only supports a percentage of the weight of the electrostatic chuck 187 (e.g., <35%) allows the remaining unsupported weight of the electrostatic chuck 187 (e.g., remaining >65%) to be used to form reliable electrical connections between the pins 240 and 242 and terminals 214 and 216 when the electrostatic chuck 187 and the substrate 186 are positioned in the processing position.

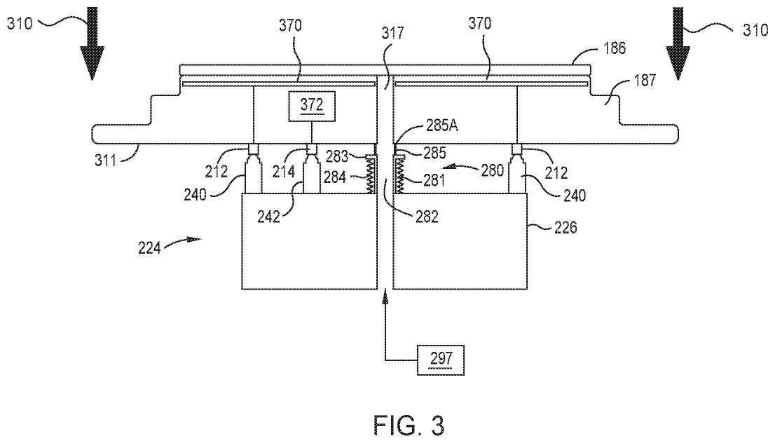

FIG. 4 illustrates a portion of the pedestal assembly 224, the electrostatic chuck 187, and the substrate 186, according to one or more embodiments. As is described above, the pedestal assembly 224 includes the compliant sealing device 380. The compliant sealing device 380 is configured similar to that of the flexible member 280, including the passageway 282 and the bellows 284. However, as compared to the single piece construction of the coupling mechanism 283 of the compliant sealing device 280, the compliant sealing device 380 comprises a coupling mechanism 383 constructed from two or more pieces. For example, the coupling mechanism 383 includes a base portion 384 and a raised element 385. The base portion 384 is part of the sealing device body 281 and constructed from a first material. Further, the raised element 385 is constructed from a second material. For example, the base portion 384 comprises a metal or metal alloy as described above. The raised element 385 comprises a ceramic material. Alternatively, the raised element 385 comprises a metal or metal alloy different from that of the base portion 384. The raised element 385 functions similar to that of the raised element 285 and has similar mating surface properties, for forming a separable seal with the opposing surface portion of the bottom surface 311 of the electrostatic chuck 187. In some embodiments, the mating surfaces 285A of the raised element 285, 385 comprises a material that is different from the material that forms the opposing surface portion of the bottom surface 311 of the electrostatic chuck 187. In one example, the mating surface 285A of the raised element 285, 385 comprises a metal, such as stainless steel (e.g., Inconel, 304 SST, 304L SST, or 316L SST) and the opposing surface portion of the bottom surface 311 includes a ceramic material, such as aluminum nitride (AlN), or boron nitride (BN). In another example, the mating surface 285A of the raised element 285, 385 comprises a ceramic material, such as alumina (Al₂O₃), aluminum nitride (AlN), or boron nitride (BN) and the opposing surface portion of the bottom surface 311 includes a ceramic material, such as aluminum nitride (AlN), or boron nitride (BN). In some embodiments, the mating surface 285A of the raised element 285, 385 includes a material that has different mechanical properties (e.g., hardness, yield strength, compressive strength, UTS) than the material used to form the bottom surface 311 of the electrostatic chuck 187. In one example, the mating surface 285A of the raised element 285, 385 includes a material that has a first hardness and the opposing surface portion of the bottom surface 311 of the electrostatic chuck 187 includes a material that has a second hardness, wherein the first hardness is different from the second hardness. In one example, the first hardness is less than the second hardness. In another example, the first hardness is greater than the second hardness.

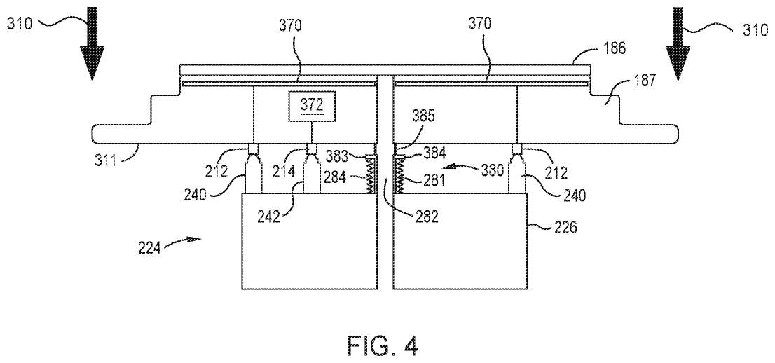

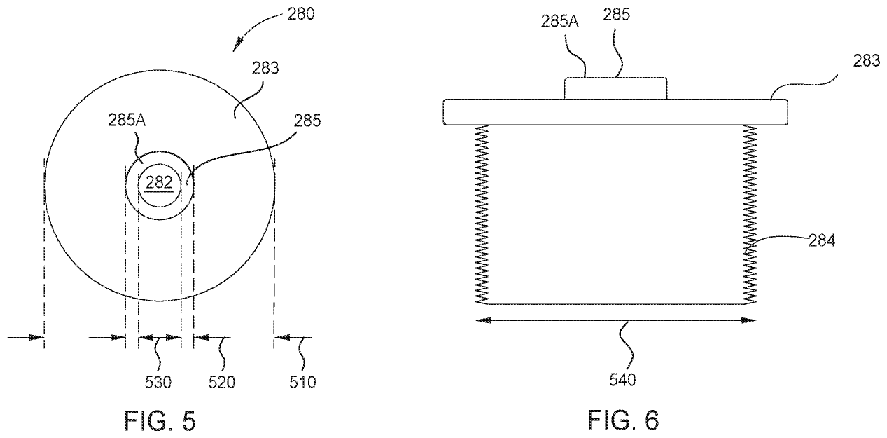

FIG. 5 illustrates a top view of the compliant sealing device 280. As illustrated in FIG. 5, the compliant sealing device 280 is cylindrical. Alternatively, the compliant sealing device 280 may have other shapes. Further, the coupling mechanism 283 and the raised element 285 have a circular shape. Alternatively, one or more of the coupling mechanism 283 and the raised element 285 has a shape other than a circular shape. Further, as illustrated in FIG. 6 the bellows 284 is cylindrical. Alternatively, the bellows 284 may have a shape other than cylindrical.

The diameter 510 of the coupling mechanism 283 is greater than the diameter 540 of the bellows 284. Alternatively, the diameter 510 of the coupling mechanism 283 may be less than or equal to the diameter 540 of the bellows 284. Further, the diameter 520 of the raised element 285 is less than the diameter 510 of the coupling mechanism 283. The diameter 530 of the passageway 282 is less than the diameter 520 of the raised element 285. In some embodiments, the diameter 520 of the raised element 285 is less than the diameter 540 of the bellows 284 such that the possible variation in the parallelism between the mating surface (e.g., top surface in FIG. 6) of the raised element 285 is minimized relative to the opposing surface (not shown in FIG. 6) of the electrostatic chuck 187.

While the foregoing is directed to embodiments of the present disclosure, other and further embodiments of the disclosure may be devised without departing from the basic scope thereof, and the scope thereof is determined by the claims that follow.

What is claimed is:

1. A substrate support for a processing region, the substrate support comprising:
a compliant sealing device comprising:
a coupling mechanism comprising a mating surface configured to interface with an opposing surface of an electrostatic chuck, wherein the mating surface is configured to form a separable seal when disposed against the opposing surface of the electrostatic chuck;
a sealing device body connected to the coupling mechanism and comprising a passageway; and
a bellows surrounding the sealing device body.

2. The substrate support of claim 1, wherein the coupling mechanism comprises a raised element that includes the mating surface.

3. The substrate support of claim 2, wherein the raised element comprises a first material and the sealing device body comprises a second material different than the first material.

4. The substrate support of claim 3, wherein the raised element comprises a ceramic and the sealing device body comprises a metal or metal alloy.

5. The substrate support of claim 2, wherein the raised element and the sealing device body comprise a first material.

6. The substrate support of claim 1, wherein the compliant sealing device is positioned in a center of the substrate support.

7. The substrate support of claim 1, wherein the compliant sealing device compresses in response to mating with the opposing surface of the electrostatic chuck.

8. A compliant sealing device comprising:
a coupling mechanism comprising a mating surface configured to interface with an opposing surface of an electrostatic chuck, wherein the mating surface is configured to form a separable seal when disposed against the opposing surface of the electrostatic chuck;
a sealing device body connected to the coupling mechanism and comprising a passageway; and
a bellows surrounding the sealing device body.

9. The compliant sealing device of claim 8, wherein the coupling mechanism comprises a raised element configured to interface with a bottom of the electrostatic chuck.

10. The compliant sealing device of claim 9, wherein the raised element comprises a first material and the sealing device body comprises a second material different than the first material.

11. The compliant sealing device of claim 10, wherein the raised element comprises a ceramic and the sealing device body comprises a metal or metal alloy.

12. The compliant sealing device of claim 9, wherein the raised element and the sealing device body comprise a first material.

13. The compliant sealing device of claim 8, wherein the sealing device body is positioned in a center of a substrate support.

14. The compliant sealing device of claim 8, wherein the bellows compresses in response to interfacing with the electrostatic chuck.

15. A processing region for processing a substrate, the processing region comprising:
a processing volume;
a gas supply; and
a pedestal assembly disposed in the processing volume and comprising a substrate support, the substrate support comprising:
a compliant sealing device comprising:
a coupling mechanism configured to interface with an electrostatic chuck;
a sealing device body connected to the coupling mechanism and comprising a passageway coupled to the gas supply; and
a bellows surrounding the sealing device body.

16. The processing region of claim 15, wherein the coupling mechanism comprises a raised element configured to interface with a bottom of the electrostatic chuck.

17. The processing region of claim 16, wherein the raised element comprises a first material and the sealing device body comprises a second material different than the first material.

18. The processing region of claim 16, wherein the raised element and the sealing device body comprise a first material.

19. The processing region of claim 15, wherein the compliant sealing device is positioned in a center of the substrate support.

20. The processing region of claim 15, wherein the compliant sealing device compresses in response to interfacing with the electrostatic chuck.
